(19) United States
(12) Patent Application Publication
(10) Pub. No.: US 2010/0089441 A1
(43) Pub. Date: Apr. 15, 2010

(54) METHOD AND APPARATUS FOR MANUFACTURING THIN-FILM PHOTOVOLTAIC DEVICES

(75) Inventors: Sergey Frolov, Murray Hill, NJ (US); Allan James Bruce, Scotch Plains, NJ (US); Michael Cyrus, Summit, NJ (US)

Correspondence Address: MAYER & WILLIAMS PC, 251 NORTH AVENUE WEST, 2ND FLOOR, WESTFIELD, NJ, 07090, US

(73) Assignee: Sunlight Photonics Inc., South Plainfield, NJ (US)

(21) Appl. No.: 12/248,864

(22) Filed: Oct. 9, 2008

(51) Int. Cl. H01L 31/042; H01L 31/18

(52) U.S. Cl. 136/255; 438/57; 136/252; 257/E31.02

(57) ABSTRACT

A method is provided for producing a thin-film device such as a photovoltaic device. The method begins by forming at least one semiconductor device on a first substrate. At least one secondary substrate having a plurality of indentations is attached to the at least one semiconductor device. The at least one semiconductor device is separated from the at least one first substrate.

### BACKGROUND

1. Field

The present invention relates generally to a method and apparatus for manufacturing thin-film photovoltaic devices, and particularly to a method and apparatus for the manufacturing of high-efficiency, multi-junction, thin-film photovoltaic devices.

2. Related Art

A variety of semiconductor devices are produced today in which semiconductor materials take the form of thin layers. These semiconductor layers may be grown epitaxially on special crystalline substrates or alternatively, these layers may be deposited as thin, polycrystalline or amorphous film on non-crystalline substrates. Various examples of such devices exist ranging from integrated electronic circuits (IC) and light emitting diodes (LED) to photovoltaic (PV) cells.

Such devices typically require thin layers of different materials. Significant improvements in the performance of these devices may be achieved by improving the optical and electrical characteristics of such layers through modification of their manufacturing methods. Furthermore, these devices are usually deposited on large area substrates. There is a continuing need to improve the performance of thin-film devices by providing substrates having characteristics that are superior to those of currently used substrates.

Photovoltaic devices, in particular, represent one of the major sources of environmentally clean and renewable energy. They are frequently used to convert optical energy into electrical energy. Typically, a photovoltaic device is made of one or more semiconducting materials with p-doped and n-doped regions. The conversion efficiency of solar power into electricity of this device is limited to an absolute theoretical maximum of about 37%, since photon energy in excess of the semiconductor's bandgap is wasted as heat. A photovoltaic device with multiple semiconductor layers of different bandgaps is more efficient: an optimized two-bandgap photovoltaic device has the maximum solar conversion efficiency of 50%, whereas a three-bandgap photovoltaic device has the maximum solar conversion efficiency of 56%. Realized efficiencies are typically less than theoretical values in all cases.

Multi-junction devices are currently manufactured as monolithic wafers, where each semiconductor layer is crystal-grown on top of the previous one. As a result, the semiconductor layers are electrically connected in series and have to be current-matched, in order to obtain maximum conversion efficiency. Furthermore, they are produced on thick, heavy and expensive wafers or other substrates, which limit the range of applications for these devices.

### SUMMARY

In accordance with the present invention, a method is provided for producing a thin-film device. The method begins by forming at least one semiconductor device on a first substrate. At least one secondary substrate having a plurality of indentations is attached to the at least semiconductor device. The at least one semiconductor device is separated from the at least one first substrate.

In accordance with another aspect of the invention, a device is provided which is formed in accordance with the aforementioned method.

In accordance with another aspect of the invention, the first substrate is an epitaxial substrate and the semiconductor device includes at least one epitaxial layer.

In accordance with another aspect of the invention, the indentations comprise holes.

In accordance with another aspect of the invention, the indentations comprise grooves.

In accordance with another aspect of the invention, the second substrate further comprises a plurality of layers and the indentations are located in a first of the plurality of layers.

In accordance with another aspect of the invention, the secondary substrate is a plastic film.

In accordance with another aspect of the invention, the secondary substrate is a metal foil.

In accordance with another aspect of the invention, the semiconductor device is a single-junction photovoltaic cell.

In accordance with another aspect of the invention, the semiconductor device is a multi-junction photovoltaic cell.

In accordance with another aspect of the invention, the multi-junction photovoltaic cell comprises at least one GaAs layer.

In accordance with another aspect of the invention, the multi-junction photovoltaic cell comprises at least one GaInP layer.

In accordance with another aspect of the invention, an electrically conducting material is disposed in the indentations. The conducting material establishes electrical contact with the semiconductor device.

In accordance with another aspect of the invention, a plurality of electrical outputs are respectively associated with the plurality of semiconductor devices.

In accordance with another aspect of the invention, a device is proved that includes a plurality of semiconductor devices formed in accordance with an epitaxial lift-off (ELO) process and removed from respective substrates on which they are formed. The device also includes a plurality of secondary substrates. The plurality of secondary substrates is respectively attached to the plurality of semiconductor devices and the pluralities of semiconductor devices and secondary substrates are arranged in a stack and attached to each other.

In accordance with another aspect of the invention, the secondary substrates comprise electrically conducting filler material disposed in indentations located therein. The semiconductor devices are electrically connected to one another in series.

In accordance with another aspect of the invention, the secondary substrates each include one or more mechanical stress relief features.

In accordance with another aspect of the invention, the secondary substrates are at least in part optically transparent.

In accordance with another aspect of the invention, the secondary substrates are electrically insulating.

In accordance with another aspect of the invention, the secondary substrates further comprise a conducting layer formed over a surface of the secondary substrate. The conducting layer electrically couples to one another the electrically conducting filler material disposed in the indentations.

### BRIEF DESCRIPTION OF THE DRAWINGS

FIGS. 1A-1C show steps in the epitaxial lift-off process.

FIG. 2 is a cross-section of a semiconductor PN junction device.

FIG. 3 is a cross-section of a multi-junction semiconductor device.

FIG. 4 is a low-stress secondary substrate.

FIG. 5 is a semiconductor device on a low-stress secondary substrate.

FIG. 6 is a semiconductor device on a low-stress conducting composite substrate.

FIGS. 7A-7C show processing steps of producing a multi-junction semiconductor device.

FIGS. 8A-8E show cross-sections of several low-stress secondary substrates.

FIG. 9 is a two-layer low-stress secondary substrate.

FIG. 10 is a two-layer low-stress secondary substrate with grooves.

FIG. 11 is a two-layer low-stress secondary substrate with stand-offs.

FIGS. 12A-12E show steps in an epitaxial lift-off process using a low-stress secondary substrate.

FIGS. 13A-13C show processing steps of producing a multi-junction semiconductor device using conducting secondary substrates.

FIGS. 14A-14C show processing steps of producing a thin-film semiconductor device using a conducting composite secondary substrate.

### DETAILED DESCRIPTION

### Overview

In the following detailed description, numerous specific details are set forth in order to provide a thorough understanding of exemplary embodiments or other examples described herein. However, it will be understood that these embodiments and examples may be practiced without the specific details. In other instances, well-known methods, procedures, components and circuits have not been described in detail, so as not to obscure the following description. Further, the embodiments disclosed are for exemplary purposes only and other embodiments may be employed in lieu of, or in combination with, the embodiments disclosed.

Semiconductor devices are typically planar multi-layered devices, in which different materials are co-deposited as relatively thin layers onto the same substrate to produce either a single large-area device, or multiple smaller-area devices. Two particular methods involved in manufacturing of such devices may be distinguished: (1) epitaxial growth and (2) thin-film deposition of semiconductor layers. In the first method, crystalline semiconductor layers are grown on top of a special substrate, which is typically made of a similar semiconductor material with matching mechanical and crystallographic characteristics. The quality of an underlying substrate in this case determines the quality of the grown semiconductor layers and thus of the overall device. In the second method, polycrystalline or amorphous semiconductor layers are deposited on top of an arbitrary substrate that has properties not necessarily matching those of deposited semiconductor materials. This method often enables low cost manufacturing of large area semiconductor devices, such as photovoltaic (PV) modules. However, not all semiconductor devices may be manufactured using the second method or may be manufactured with the same high performance characteristics as those of the devices produced by the first method.

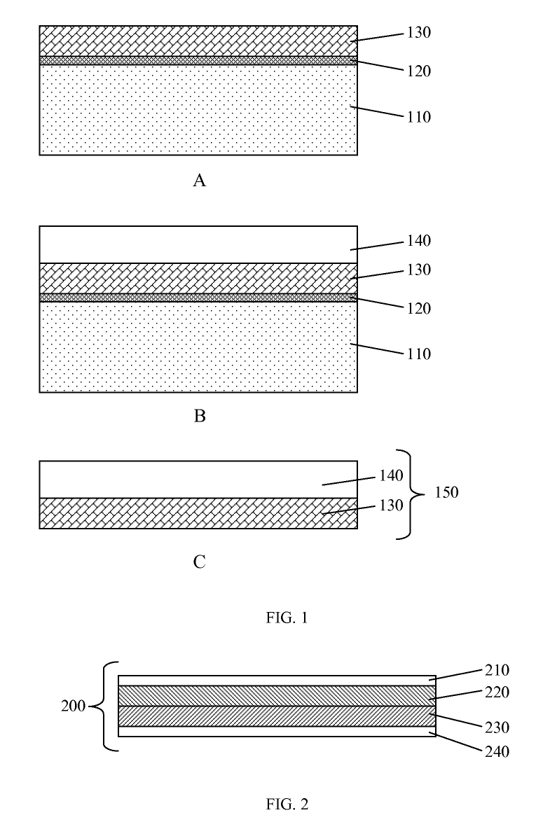

A hybrid method of manufacturing has been also developed called an epitaxial lift-off (ELO) process, in which a semiconductor PV device is first produced using the first approach, as shown in FIG. 1(A). First, a multi-layered device 130 is grown on a special substrate 110. The substrate 110 may be an epitaxial substrate and the multilayered device 130 may include epitaxial layers that have been grown on the epitaxial substrate. An intermediate layer 120 may be also produced between substrate 110 and device 130. A secondary substrate 140 is then attached to device 130, as shown in FIG. 1(B). Substrate 140 may be eventually used as a thin carrier substrate. Subsequently, the original substrate 110 is separated from device 130 to produce a thin-film device 150, as shown in FIG. 1(C). In this case substrate 110 may be lifted off by polishing, chemical etching, mechanical cleaving or other means. Intermediate layer 120 may be used to facilitate the lift-off process, e.g. by providing a buffer layer for the polishing process or an etch stop layer for the etching lift-off process. Alternatively, intermediate layer 120 may be etched away, in which case the underlying substrate 110 may be recycled and subsequently used in the production process. As described below, device 130 may be a multi-layered semiconductor planar device.

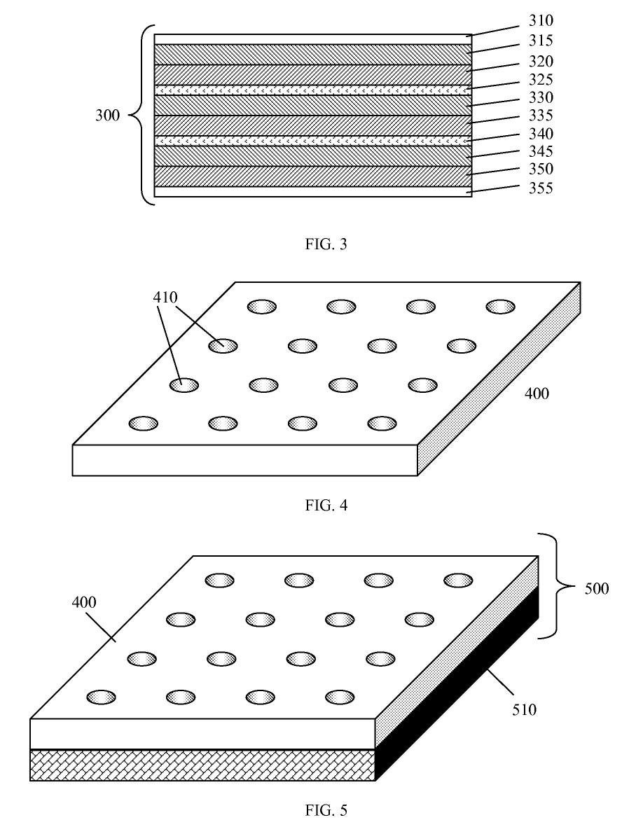

For example, FIG. 2 shows a semiconductor PN junction device 200, which may function as a PV cell. Device 200 consists of at least two semiconductor layers 220 and 230, which are doped to provide P-type and N-type conductivities, respectively. Additional conducting layers 210 and 240 may be used to provide low-resistance contacts. Often, at least one of the conducting layers 210 and 240 is an optically transparent layer. In another example, FIG. 3 shows a multi-junction semiconductor device 300, which may function as a high-efficiency PV cell. Device 300 consists of three PN junctions (other multiples are also possible). There may be several semiconductor layers numbered 315, 320, 330, 335, 345 and 350, which are doped to provide alternate P-type and N-type conductivities. Also, there may be buffer layers 325 and 340, which bind and electrically interconnect neighboring junction layers. In addition, conducting layers 310 and 355 may be provided for low resistance contacts.

In a typical ELO process, it is sometimes necessary to use a secondary substrate (e.g. substrate 140) with a thermal expansion coefficient matching that of a semiconductor device being lifted-off (e.g. device 130). Also, typically such a substrate is rigid and inflexible, and generally will not be both highly transparent and electrically conductive. Alternatively, one may use a thin, flexible secondary substrate, which would reduce the weight and cost of the resulting device (e.g. device 150). However, it has been found that such substrates often lead to micro-cracking in semiconductor films and subsequent device failure, due to mechanical stresses produced by the secondary substrate after the ELO process is completed. In one aspect, this invention provides a modified secondary substrate that substantially reduces mechanical stresses experienced by a semiconductor device after the ELO process. Such a low-stress substrate may consist of one or more layers, which may be produced from one or more materials. Furthermore, at least one of these layers may be perforated either partially or completely as shown in FIG. 4. Secondary substrate 400 is produced here in such a way as to include openings, holes or indentations 410 that function as mechanical stress relief features. Due to its lower stress, such a substrate may be bonded, soldered, glued or attached by other means to a planar semiconductor device 510 for an ELO procedure and produce a thin-film device 500 shown in FIG. 5 without micro-cracking and subsequent device failure. Substrate 400 may be made optically transparent or opaque, electrically conductive or insulating.

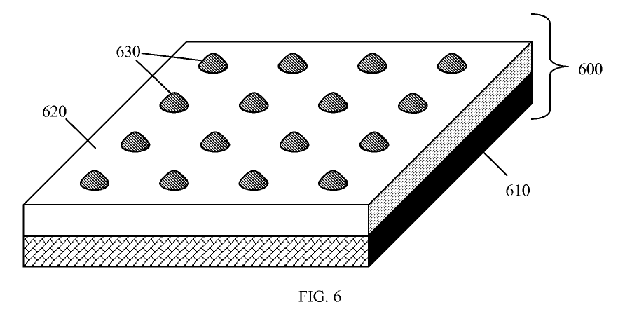

In another aspect, this invention provides a modified secondary substrate that is advantageously both at least partially transparent and electrically conducting. This substrate may consist of at least one electrically insulating layer that is perforated and the perforations are filled with electrically conducting material. FIG. 6 shows a semiconductor device 600 produced by an ELO process using such a substrate that is comprised of a perforated non-conducting layer 620 and electrically conducting filler material 630. Perforated non-conducting layer 620 and electrically conducting filler material 620 may thus form a composite conducting substrate. Filler material may be added before, during or after the ELO process. Such a substrate may simultaneously be substantially transparent and electrically conducting, both of which are attractive features for PV cell manufacturing.

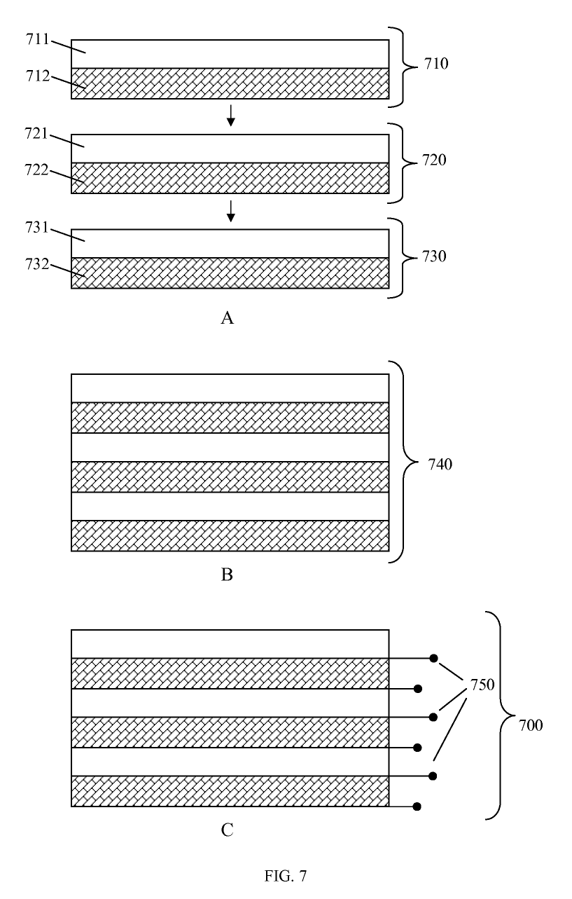

In another aspect of this invention, a method is provided for producing a stacked multi-junction PV cell from separate PV cells that were produced on different primary substrates and subsequently lifted-off. For example, FIG. 7 shows a simplified sequence of processing steps (FIGS. 7A,7B and 7C) for making a three-junction device 700, in which separate PV cells 710, 720 and 730 are first produced by ELO respectively using secondary substrates 711, 721 and 732 and planar devices 712, 722 and 732 (FIG. 7A). Then PV cells are attached to each other to produce a multi-junction stack 740 (FIG. 7B). The secondary substrates may be electrically conducting, so that devices 712, 722 and 732 are connected in series. Alternatively, the secondary substrates may be electrically insulating, so that separate electrical contacts 750 may be provided for each semiconductor device 712, 722 and 732. Also, the substrates in this stack may be at least partially transparent, so it may function as a high-efficiency PV cell. Similarly, any number of PV cells larger than one may be stacked using this approach to achieve a power conversion efficiency higher than that of a single-junction cell.

This method provides an alternative approach to producing a multi-junction PV device. As well known in the art, multi-junction devices in general are one of the most efficient means for converting solar energy into electricity. Currently, the best performing solar cells are based on epitaxially grown, crystalline semiconductor multijunctions. These are complex devices, which are manufactured using difficult and expensive manufacturing processes and their high cost can make them prohibitive for wide spread use and high volume production. This invention, on the other hand, proposes to use a less complex and expensive hybrid manufacturing process. Using multi-junction design and thin-film manufacturing approaches, a new efficient photovoltaic device with expanded capabilities and application range can be produced.

Current approaches to the design of multi-junction devices usually result in production of serially connected junctions. As a result, an electrical current through each junction must be the same; this is a condition called current matching and it is accomplished by careful selection of semiconductor bandgaps and layer thicknesses given a predetermined shape of the light spectrum. This current matching may unduly complicate the design of the device, reduce its fault tolerance and may also reduce its conversion efficiency. For example, a failure of one junction will result in a failure of the whole device. Furthermore, under changing environmental conditions the spectrum of light used for energy conversion may change substantially. This effect may in turn lead to disproportionately different changes of current in different junctions, thus breaking the current matching condition and reducing conversion efficiency.

It is another aspect of this invention to overcome the problems arising from serially connected junctions by providing separate electrical contacts for each junction layer in a multi-junction device. For example, in a multi-junction PV cell 700, each contact pair 750 acts as a separate, independent photovoltaic source, thus producing n sets of currents and voltages: from I₁ and V₁, I₂ and V₂, to I₃ and V₃. This provision eliminates the need for the current matching condition, which in turn results in a simpler design of a cell and its manufacturing process, a more robust and fault tolerant performance, higher conversion efficiency and an adaptive capability with respect to changes in the spectral content of light used for conversion. More specifically, the latter property of the multi-junction PV device, referred to as spectral adaptation, allows the photovoltaic device to operate at its maximum possible efficiency regardless of any optical filtering effects that may occur during its operation. That is, with spectral adaptation, if the spectral content or profile of the optical energy changes, the conversion efficiency of the device will not decrease to as large an extent as it would if the junctions in the device were required to be current matched. This is because the operation of each junction can be largely tailored to the spectral content of the optical energy independent of the other junctions in the device. Also, a failure of any of the thin-film junction layers will not result in failure of the whole device, since they are electrically insulated.

### EXAMPLES

Variations of the apparatus and method described above are possible without departing from the scope of the invention.

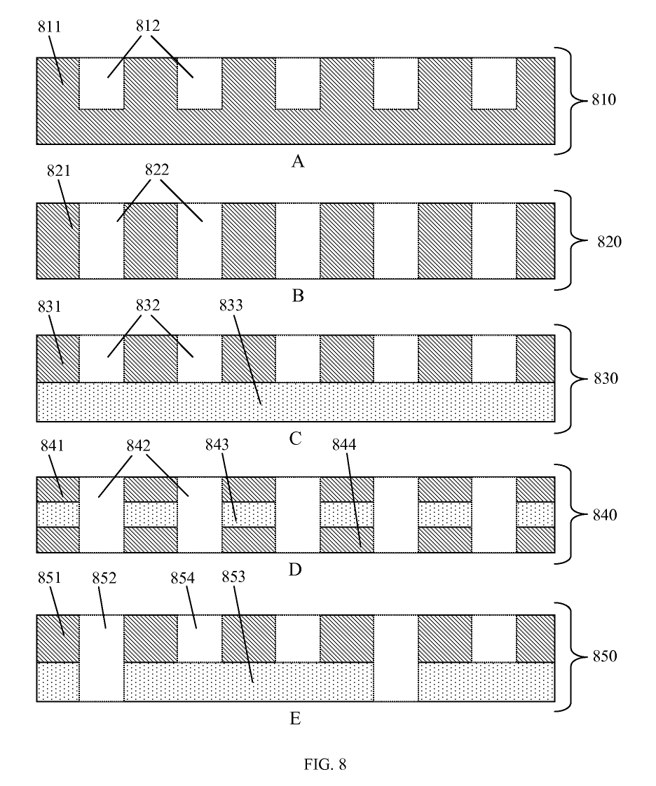

FIG. 8 shows cross-sections of several exemplary embodiments of a secondary substrate, or otherwise known as a carrier substrate, having low-stress characteristics. In FIG. 8A the low-stress substrate 810 consists of single material layer 811 having an array of indentation, notches or grooves 812. In FIG. 8B the low-stress substrate 820 consists of a single material layer 821 having an array of perforations or through holes 822. In FIG. 8C the low-stress substrate 830 consists of two layers 831 and 833, one of which having an array of perforations or through holes 832. In FIG. 8D the low-stress substrate 840 consists of three layers 841, 843 and 844, all of which are perforated with an array of through holes 842. In FIG. 8E the low-stress substrate consists of two layers 851 and 853 having an array of perforations or through holes 852 and an array of indentation, notches or grooves 854. These holes, indentations and grooves may be arranged in various two-dimensional patterns, similar to or different from the one shown in FIG. 4. Alternative patterns may include hexagonal, triangular, irregular and other patterns.

The carrier substrate may be produced as a single layer from a single material. For example, a non-conducting transparent carrier may be produced using a sheet of low-cost plastic film, such as polyimide, silicone, polyethylene terephthalate (PET) or others. A conducting carrier may be produced using a metal foil, such as stainless steel foil, aluminum foil, copper tape or others. Alternatively, a carrier substrate may be produced as from multiple layers of a single material or multiple materials. One or more layers in the substrate may be used to better match thermal expansion of an attached semiconductor device to avoid micro-cracking. Other materials may be used for this purpose, such as glass, sapphire, thin polycrystalline semiconductor films and others. For example, a layer of polycrystalline GaAs, Ge or sapphire may be used to match the expansion of GaAs-based semiconductor device.

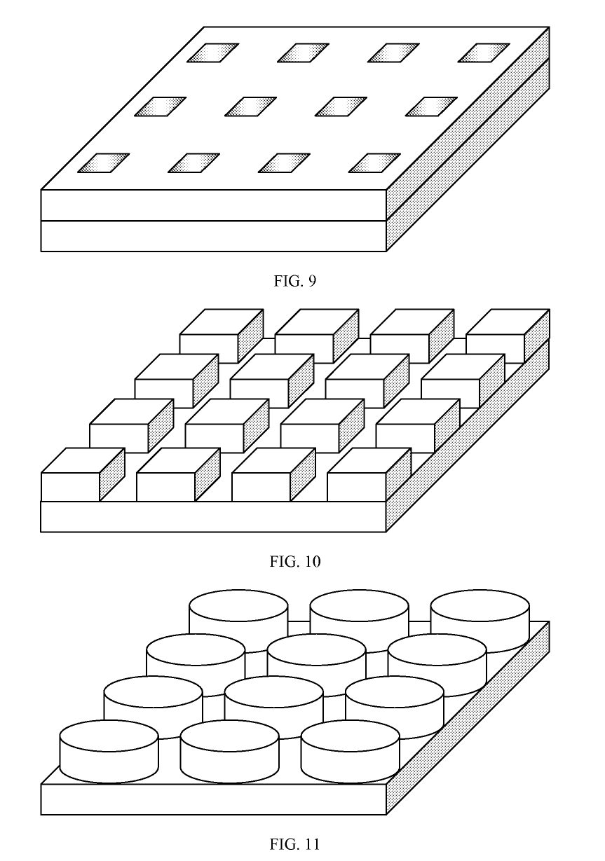

Perforations, indentations, holes and grooves may be used to decrease the amount of stress produced by the carrier substrate. For example, a pattern of round holes or indentations 410, as shown in FIG. 4, may be used to relieve stress in substrate 400. In some embodiments holes may be 1 to 100 microns in diameter, and preferably 10 to 50 microns in diameter. These holes may be spaced 10 to 1000 microns apart, for example, and preferably 50 to 250 microns apart. Alternatively shaped indentations and holes may be used to produce stress-relieving features in a carrier substrate. For example, FIG. 9 shows a two-layer carrier substrate with an array of square-shaped holes. Furthermore, grooves may be used to produce stress-relief patterns in a carrier substrate. For example, FIG. 10 shows a carrier substrate with an array of grooves producing a pattern of square-shaped stand-offs. Similarly, alternatively shaped stand-offs may be produced using indentations, such as for example disk-shaped patterns shown in FIG. 11.

Various techniques and methods may be used to produce such patterns of indentations and holes. These patterns could be produced using punching or perforator machines. This technique may be a low-cost approach to produce a large volume of carrier substrates. Alternatively, similar patterns may be produced using etching or micro-stamping techniques. The advantage of these approaches is in their ability to produce finer features with better resolution. Furthermore, other techniques may be used, such as machining, sawing, laser drilling, molding and others.

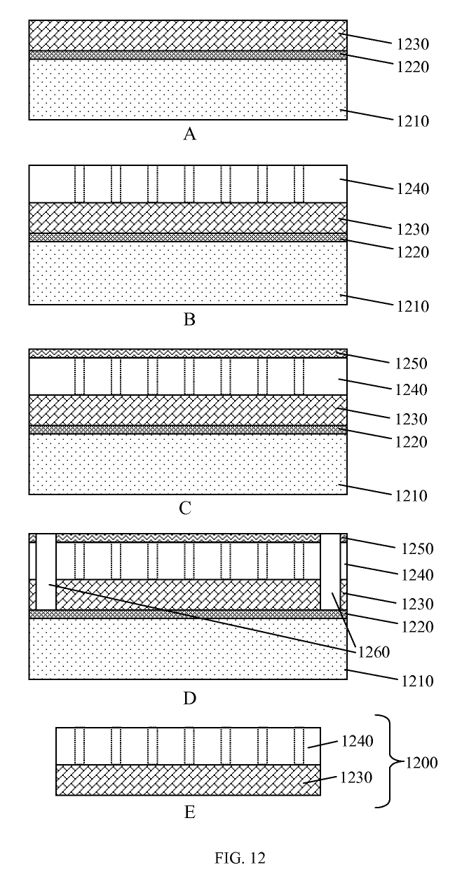

In another embodiment of this invention FIG. 12 illustrates an ELO process utilizing a low-stress substrate. First, a semiconductor device 1230 may be produced on a primary substrate 1210 and an intermediate buffer layer 1220, as shown in FIG. 12A. The primary substrate 1210 may be an epitaxial substrate and the semiconductor device 1230 may include epitaxial layers that have been grown on the epitaxial substrate. [Second, a low-stress substrate 1240 may be attached to device 1230, as shown in FIG. 12B. Third, a patterning layer 1250, such as a photoresist layer, may be deposited onto substrate 1240, as shown in FIG. 12C. Fourth, layer 1250 may be patterned, e.g. using photolithographic patterning, and subsequently a pattern 1260 may be etched into substrate 1240 and device 1230, as shown in FIG. 12D. Fifth, this ELO process may be completed by etching buffer layer 1220, which separates device 1230 from primary substrate 1210, and thus produce a free-standing device 1200, as shown in FIG. 12E. Low stress substrate 1240, which serves as a carrier substrate may be produced from a thin flexible material as described above, so that the resulting device 1200 possesses characteristics of an epitaxially grown semiconductor, such as high performance, and characteristics of thin-film devices, such as light weight and flexibility. Various attachment techniques may be used to affix carrier substrate 1240 to device 1230; for example, the bottom side of substrate 1240 may be coated with a thin layer of adhesive and laminated on top of device 1230. The last etching step in the described ELO process may be a wet etching process utilizing HF. Other lift-off processes may be designed, which may also use a low-stress substrate.

An ELO process may be applied to multiple planar semiconductor devices. Such devices may be multiple PV cells with different designs. Two or more PV cells may be designed so that they may work well together in a single stack. For example, if the bandgaps of corresponding semiconductor absorber layers in these PV cell are different, a PV cell with a larger bandgap may be positioned above a PV cell with a smaller bandgap. The conversion efficiency of a resulting stack of cells may be higher than the conversion efficiency of either cell separately. This approach is illustrated in FIG. 7A, where three separate thin-film devices or cells 710, 720 and 730 are first produced using ELO on transparent carrier substrates 711, 721 and 731, respectively. The carrier substrates 711, 721 and 731 may be epitaxial substrates and the cells 710, 720 and 730 may include epitaxial layers that have been respectively grown on the epitaxial substrates In this case ELO processes may also benefit from and utilize the low-stress carrier substrates and thus may be similar to the ELO process described above and shown in FIG. 12. Semiconductor devices 712, 722 and 732 may be PV devices and include PN junction layers with corresponding absorber semiconductor bandgaps E₁, E₂ and E₃, respectively. They may be arranged in a stack, where E₁>E₂>E₃, and laminated together to produce a multi-junction PV device 740, as shown in FIG. 7B, so that light may be first partially absorbed by the top device 710, followed by device 720, and then by device 730. For example, device 712 may include Ga_{0.5}In_{0.5}P layer with bandgap E₁=1.83 eV, device 722 may include GaAs layer with bandgap E₂=1.40 eV, and device 732 may include In_{0.27}Ga_{0.73}As with bandgap E₁=1.00 eV. Alternatively, the orientation of the devices 710, 720 and 730 may be opposite of the orientation shown in FIG. 7, so that carrier substrates 711, 721 and 731 are at the bottom.

Device 740 may be produced using insulating carrier substrates 711, 721 and 731, in which case separate electrical contacts 750 may be provided as shown in FIG. 7C. Such contacts may be provided before or after the lamination procedure. Laminated layers may be offset to provide open areas for contact attachment. The advantage of such arrangement is that it avoids a so-called current matching condition and thus substantially increases the scope of applications for such a device. For example, currently produced multi-junction cells are all limited by the current matching condition and thus may function well only in specific environments with fixed conditions, such as for instance orbital space. In environments with varying illumination conditions, such as terrestrial, their efficiency may drop dramatically, however, so that their usage in these conditions may not be economically viable. On the other hand device 700 will not suffer from the same drawback and operate at best possible efficiency in all conditions. The disadvantage of this device design is that it may increase the number of DC contacts, wires and cables in a PV system that may use such PV devices.

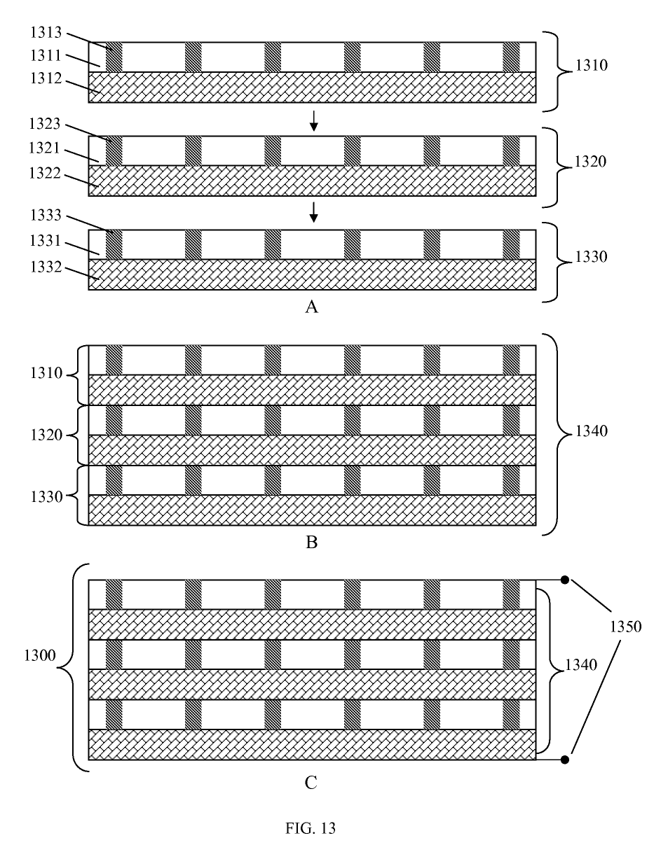

Alternatively, as illustrated in FIG. 13, device 1300 may be produced using composite conducting substrates 1311, 1321 and 1331, similar to the composite carrier substrate shown in FIG. 6. Three separate thin-film devices 1310, 1320 and 1330 (FIG. 13A) are first produced using ELO on composite carrier substrates 1311, 1321 and 1331, respectively, which may also be low-stress substrates and include electrically conducting filler materials 1313, 1323 and 1333. Semiconductor devices 1312, 1322 and 1332 may be PV devices and include PN junction layers with corresponding absorber semiconductor bandgaps E₁, E₂ and E₃, respectively. They may be selected from a group of PV devices based on GaAs, InGaAs, GaInP, CdTe, crystalline Si, polycrystalline Si, microcrystalline Si, nanocrystalline Si, amorphous Si, Ge, CuInSe₂, CuInₓGa₁₋ₓS_{y}Se_{1-y}, and other inorganic semiconductors. In addition, organic and polymer semiconductors may be used. The three devices may be arranged in a stack, where E₁>E₂>E₃, and bonded together to produce a multi-junction PV device 1340, as shown in FIG. 13B. During the attachment process, in-series electrical connection may be provided between neighboring devices, such that device 1310 may be connected to device 1320, which in turn may be connected to device 1330 in series. Such electrical connection may be achieved by soldering or applying conducting epoxy. Furthermore, a completed high-efficiency multi-junction cell 1300 may be produced by providing two electrical terminals 1350, as shown in FIG. 13 C. In this design, the performance of device 1300 may be limited by the current matching condition. However, its usage may be greatly facilitated by the smaller number of output electrical terminals.

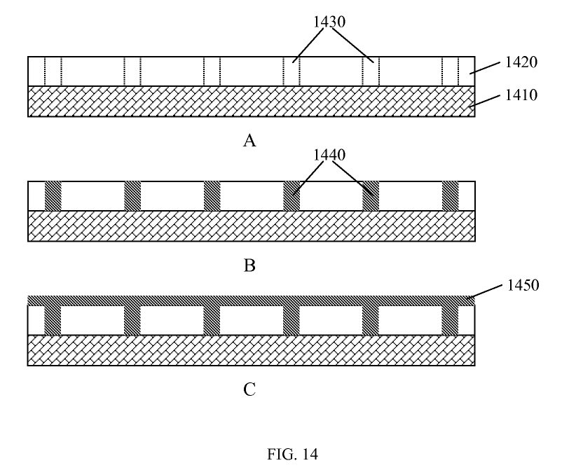

In another embodiment of this invention shown in FIG. 14, a semiconductor device 1410 may be produced by ELO using a low-stress carrier substrate 1420 with perforations 1430 (FIG. 14A). Subsequently, perforations 1430 may be filled with a conducting material, e.g. a conducting ink may be deposited by direct writing (FIG. 14B). Additionally, another conducting layer 1450 may be deposited on top of the substrate 1430 (FIG. 14C), e.g. a metal film (Al, Au, Ag, Ni/Al, etc) may be sputtered or evaporated. Furthermore, layer 1450 may be patterned and function as a current collector or a bus for device 1410. Device 1410 may be a single junction or a multi-junction PV device.

What is claimed is:

1. A method of producing a thin-film device, comprising:
forming at least one semiconductor device on a first substrate;
attaching at least one secondary substrate having a plurality of indentations to said at least semiconductor device; and
separating said at least one semiconductor device from said at least one first substrate.

2. A device formed in accordance with the method set forth in claim 1.

3. The device of claim 2 wherein the first substrate is an epitaxial substrate and the semiconductor device includes at least one epitaxial layer.

4. The device of claim 2 wherein said indentations comprise holes.

5. The device of claim 2 wherein said indentations comprise grooves.

6. The device of claim 2 wherein said second substrate further comprises a plurality of layers and said indentations are located in a first of the plurality of layers.

7. The device of claim 2 wherein said secondary substrate is a plastic film.

8. The device of claim 2 wherein said secondary substrate is a metal foil.

9. The device of claim 2 wherein said semiconductor device is a single-junction photovoltaic cell.

10. The device of claim 2 wherein said semiconductor device is a multi-junction photovoltaic cell.

11. The device of claim 10 wherein said multi-junction photovoltaic cell comprises at least one GaAs layer.

12. The device of claim 10 wherein said multi-junction photovoltaic cell comprises at least one GaInP layer.

13 The device of claim 2 further comprising electrically conducting material disposed in said indentations, said conducting material establishing electrical contact with said semiconductor device.

14. The device of claim 2 wherein said at least one semiconductor device comprises a plurality of semiconductor devices and said at least one second substrate comprises a plurality of second substrates, said pluralities of semiconductor devices and second substrates being arranged in a stack and attached to each other.

15. The device of claim 14 further comprising a plurality of electrical outputs respectively associated with the plurality of semiconductor devices.

16. The device of claim 14 wherein said secondary substrates further comprise electrically conducting filler material disposed in their respective indentations and said plurality of semiconductor devices are electrically connected to one another in series.

17. The method of claim 1 wherein said at least one semiconductor device comprises a plurality of semiconductor devices and said at least one second substrate comprises a plurality of second substrates, said pluralities of semiconductor devices and second substrates being arranged in a stack and attached to each other.

18. A device comprising
a plurality of semiconductor devices formed in accordance with an epitaxial lift-off (ELO) process and removed from respective substrates on which they are formed;
a plurality of secondary substrates; said plurality of secondary substrates being respectively attached to the plurality of semiconductor devices and said pluralities of semiconductor devices and secondary substrates being arranged in a stack and attached to each other.

19. The device of claim 18 further comprising a plurality of electrical outputs matching a plurality of semiconductor devices.

20. The device of claim 18 wherein said secondary substrates comprise electrically conducting filler material disposed in indentations located therein, said plurality of semiconductor devices being electrically connected to one another in series.

21. The device of claim 18 wherein said secondary substrates each include one or more mechanical stress relief features.

22. The device of claim 18 wherein said secondary substrates are at least in part optically transparent.

23. The device of claim 18 wherein said secondary substrates are electrically insulating.

24. The device of claim 20 wherein the secondary substrates further comprise a conducting layer formed over a surface of the secondary substrate, said conducting layer electrically coupling to one another the electrically conducting filler material disposed in the indentations.
